(19) United States
(12) Patent Application Publication
(10) Pub. No.: US 2012/0321106 A1
(43) Pub. Date: Dec. 20, 2012

(54) CONDENSER MICROPHONE

(76) Inventor: Kang-Chao Chang, Chiayi City (TW)

(21) Appl. No.: 13/164,165

(22) Filed: Jun. 20, 2011

(51) Int. Cl. H03F 99/00

(52) U.S. Cl. 381/120

(57) ABSTRACT

A condenser microphone includes: a true condenser microphone (TCM) pickup operable to generate an input signal at a high impedance corresponding to sound picked up thereby; an impedance conversion circuit connected electrically to the TCM pickup, and operable to convert the input signal from the TCM pickup to a converted signal at a low impedance; an amplifier circuit connected electrically to the impedance conversion circuit, disposed to receive a power signal, and operable for amplifying the converted signal so as to generate an output signal; and a phantom voltage module connected electrically to the TCM pickup, disposed to receive the power signal, and operable for generating a phantom signal from the power signal, the phantom signal having a voltage higher than that of the power signal and being provided to the TCM pickup for charging the TCM pickup.

### BACKGROUND OF THE INVENTION

1. Field of the Invention

The present invention relates to a condenser microphone, more particularly to a non-electret condenser microphone.

2. Description of the Related Art

Shown in FIG. 1 is a circuit of a conventional condenser microphone having an electret pickup 11, and an amplifier circuit 12 comprised of operational amplifiers. The electret pickup 11 is operable to generate an electrical signal corresponding to sound picked up thereby. The amplifier circuit 12 is connected electrically to the electret pickup 11 for receiving the electrical signal therefrom, and is operable to amplify the electrical signal so as to generate an amplified electrical signal for subsequent processing.

The electret pickup 11 is characterized by excellent sound-pickup sensitivity. However, since the electret pickup 11 utilizes a quasi-permanently charged dielectric material, the sound-pickup sensitivity of the electret pickup 11 is susceptible to gradual deterioration caused by aging of the quasi-permanently charged dielectric material.

### SUMMARY OF THE INVENTION

Therefore, an object of the present invention is to provide a condenser microphone capable of alleviating the aforesaid drawbacks of the prior art.

Accordingly, a condenser microphone of the present invention includes:

a true condenser microphone (TCM) pickup operable to generate an input signal at a high impedance corresponding to sound picked up thereby;

an impedance conversion circuit connected electrically to the TCM pickup, and operable to convert the input signal from the TCM pickup to a converted signal at a low impedance;

an amplifier circuit connected electrically to the impedance conversion circuit, disposed to receive a power signal, and operable for amplifying the converted signal so as to generate an output signal; and

a phantom voltage module connected electrically to the TCM pickup, disposed to receive the power signal, and operable for generating a phantom signal from the power signal, the phantom signal having a voltage higher than that of the power signal and being provided to the TCM pickup for charging the TCM pickup.

### BRIEF DESCRIPTION OF THE DRAWINGS

Other features and advantages of the present invention will become apparent in the following detailed description of the preferred embodiment with reference to the accompanying drawings, of which:

FIG. 1 is a circuit diagram to illustrate a conventional condenser microphone; and

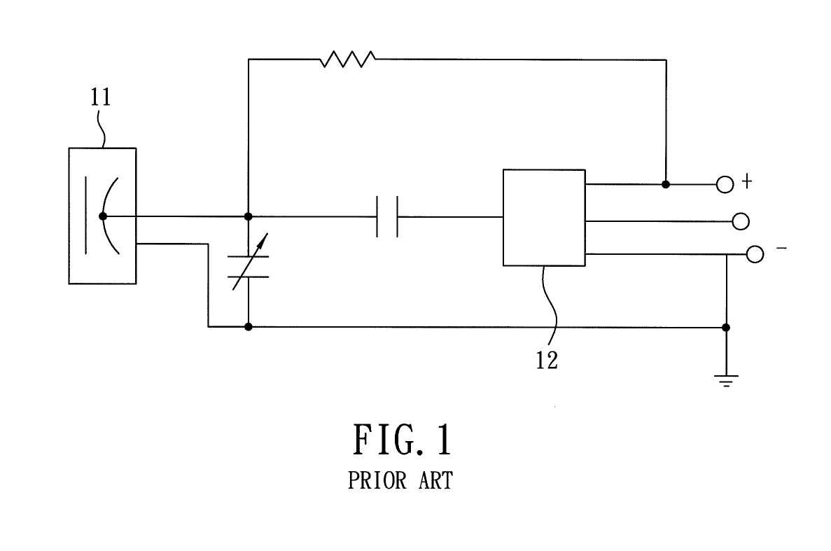

FIG. 2 is a circuit diagram to illustrate the preferred embodiment of a condenser microphone according to the present invention.

### DETAILED DESCRIPTION OF THE PREFERRED EMBODIMENT

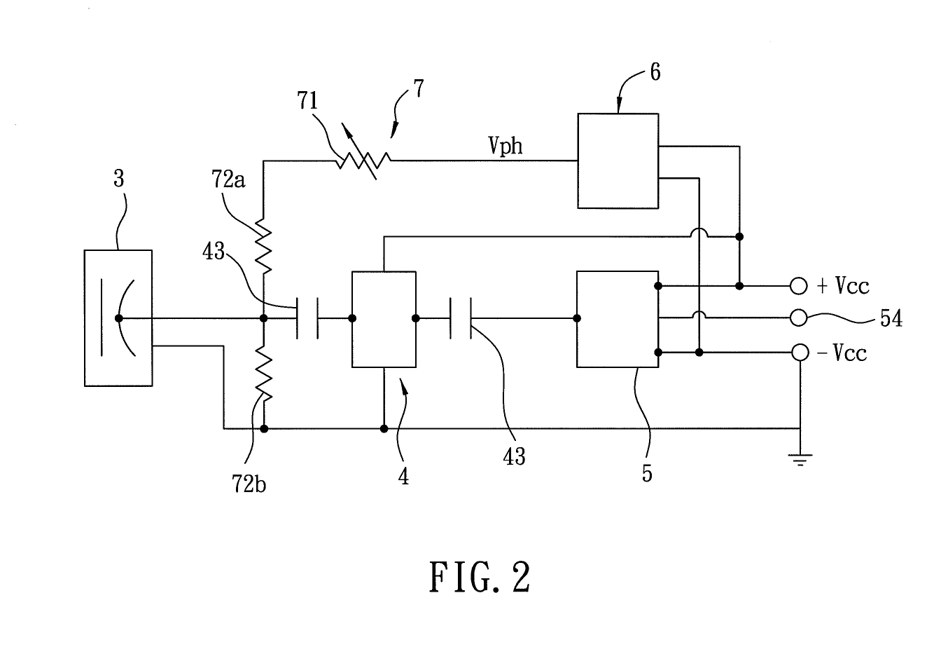

Referring to FIG. 2, the preferred embodiment of a condenser microphone according to the present invention includes a true condenser microphone (TCM) pickup 3, an impedance conversion circuit 4, an amplifier circuit 5, and a phantom voltage module that includes a phantom voltage generator 6 and a phantom voltage adjusting circuit 7.

The TCM pickup 3 is not subjected to polarization processing, and is operable to generate an input signal at a high impedance corresponding to sound picked up thereby.

The impedance conversion circuit 4 is disposed to receive a power signal “V_{cc}” from such as a 5V battery, is connected electrically to the TCM pickup 3, and is operable to convert the input signal from the TCM pickup 3 to a converted signal at a low impedance, thereby reducing influence of external noise and interference. In this embodiment, the impedance conversion circuit 4 is electrically interconnected between two coupling capacitors 43, which serve to reduce power backflow. Since a skilled artisan may readily appreciate the function and the appropriate arrangement of a coupling capacitor, the coupling capacitors 43 will not be described in greater detail hereinafter for the sake of brevity.

The amplifier circuit 5 is comprised of a plurality of operational amplifiers, is disposed to receive the power signal “V_{cc}”, is connected electrically to the impedance conversion circuit 4 for receiving the converted signal therefrom, and is operable for amplifying the converted signal so as to generate an output signal for outputting via such as an output node 54. Configuration and connection arrangement of the amplifier circuit 5 in a microphone application is well known in the art, and hence will not be described in greater detail hereinafter for the sake of brevity.

The phantom voltage generator 6 is disposed to receive the power signal “V_{cc}”, and is operable to generate from the power signal “V_{cc}” an intermediate phantom signal “Vₚₕ” having a voltage higher than that of the power signal “V_{cc}”. The phantom voltage adjusting circuit 7 includes a variable resistor 71 connected to the phantom voltage generator 6, a first resistor 72a connected to the variable resistor 71, and a second resistor 72b connected to the first resistor 72a. The TCM pickup 3 is connected across the second resistor 72b in this embodiment, but may be connected across the first resistor 72a in other embodiments. The variable resistor 71 may be adjusted such that a potential difference in the TCM pickup 3 matches an optimal operating voltage of the TCM pickup 3, thereby optimizing sound-pickup sensitivity of the TCM pickup 3.

Since condenser microphones have substantially non-uniform sound-pickup sensitivities after the condenser microphones are manufactured, such a sensitivity adjustment mechanism may be useful for fine-tuning the sound-pickup sensitivities of the condenser microphones to a predetermined level. Furthermore, the sensitivity adjustment mechanism may be utilized to maintain the sound-pickup sensitivity at the predetermined level when the sound-pickup sensitivity starts to vary due to ageing of the TOM pickup 3 after long-term use.

It is worth noting that a conventional wireless microphone generally has an operating voltage of 5V, which is insufficient to charge the pickup of the wireless microphone to a state where an optimal amount of charges may be accumulated therein. Consequently, the conventional wireless microphone has a relatively poor sound-receiving sensitivity. In contrast, in this embodiment, by virtue of the phantom voltage module, the TCM pickup 3 is operable at the optimal operating voltage thereof, thereby exhibiting optimal sound-pickup sensitivity.

In summary, by virtue of the phantom voltage generator 6 and the phantom voltage adjusting circuit 7, the TCM pickup 3 is operable at the optimal operating voltage thereof such that the TCM pickup 3 is able to exhibit the optimal sound-pickup sensitivity. Furthermore, the variable resistor 71 may be adjusted for adjusting the operating voltage of the TCM pickup 3, thereby adjusting the sound-pickup sensitivity of the TCM pickup 3. Moreover, by virtue of the impedance conversion circuit 4, the TCM pickup 3 is less susceptible to external interference and noise.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A condenser microphone comprising:
a true condenser microphone (TCM) pickup operable to generate an input signal at a high impedance corresponding to sound picked up thereby;
an impedance conversion circuit connected electrically to said TCM pickup, and operable to convert the input signal from said TCM pickup to a converted signal at a low impedance;
an amplifier circuit connected electrically to said impedance conversion circuit, disposed to receive a power signal, and operable for amplifying the converted signal so as to generate an output signal; and
a phantom voltage module connected electrically to said TCM pickup, disposed to receive the power signal, and operable for generating a phantom signal from the power signal, the phantom signal having a voltage higher than that of the power signal and being provided to said TCM pickup for charging said TCM pickup.

2. The condenser microphone as claimed in claim 1, wherein said phantom voltage module includes:
a phantom voltage generator disposed to receive the power signal and operable for generating an intermediate phantom signal from the power signal; and
a phantom voltage adjusting circuit connected electrically between said TCM pickup and said phantom voltage generator, receiving the intermediate phantom signal, operable to generate adjustably the phantom signal from the intermediate phantom signal, and providing the phantom signal to said TCM pickup.

3. The condenser microphone as claimed in claim 2, wherein said phantom voltage adjusting circuit includes a variable resistor and a resistor unit interconnected electrically in series between said phantom voltage generator and said TCM pickup.

4. The condenser microphone as claimed in claim 3, wherein said variable resistor is connected to said phantom voltage generator and said resistor unit includes a first resistor connected to said variable resistor and a second resistor connected to said first resistor, said TCM pickup being connected across one of said first and second resistors.

5. The condenser microphone as claimed in claim 1, wherein said amplifier circuit includes an operational amplifier.
